(19) United States
(12) Patent Application Publication
(10) Pub. No.: US 2026/0261030 A1
(43) Pub. Date: Sep. 3, 2026

(54) Multi-Layer Waveguide Transitions

(71) Applicant: Gapwaves AB, Göteborg (SE)

(72) Inventors: Abbas VOSOOGH, Göteborg (SE); Carlo BENCIVENNI, Göteborg (SE)

(21) Appl. No.: 19/163,149

(22) PCT Filed: Mar. 6, 2024
(86) PCT No.: PCT/SE2024/050205

§ 371 Date: Sep. 8, 2025

(30) Foreign Application Priority Data
Mar. 8, 2023 (SE) 2350259-4

(51) Int. Cl. H01P 3/123

(52) U.S. Cl. CPC H01P 3/123

(57) ABSTRACT

The present disclosure relates to a multi-layer waveguide transition, an inter-waveguide transition and a waveguide T-junction. The waveguide transition comprises a top layer, at least one intermediate layer, and at least one bottom layer. The at least one intermediate layer comprises an elongated waveguide channel. A metasurface is arranged to surround the elongated waveguide channel. The metasurface is arranged between the top layer and the at least one intermediate layer and between the bottom layer and the at least one intermediate layer. Additionally, the waveguide transition comprises a port opening arranged in the bottom layer overlapping with a coupling portion of the elongated waveguide channel. A central conductor is arranged in the elongated waveguide channel.

### TECHNICAL FIELD OF THE INVENTION

The present invention relates to transition arrangements between waveguides, more specifically transition arrangements between waveguides comprising multiple physical layers.

### BACKGROUND OF THE INVENTION

Different types of waveguides or transmission lines are commonly used to route electromagnetic waves to and/or from electronic components. For instance, a waveguide or transmission line is commonly used to route electromagnetic waves of a transmitter to one or more antennas whereby the antenna emits the electromagnetic waves into the air, allowing wireless transmission of data.

There exist many different types of waveguides including hollow waveguides (such as conventional rectangular hollow waveguides) and transmission lines which are integrated into, or arranged on top of, a substrate layer such as a microstrip line, a stripline or a coplanar transmission line. Each type of waveguide or transmission line can further be adapted for different operational frequencies. For instance, for hollow rectangular waveguides the dimensions of the waveguide are reduced as the operational frequency is increased to ensure that only a single mode can propagate through the waveguide.

More recently, much research has been conducted regarding other types of waveguides, such as gap waveguides where a first layer with a metamaterial structure of protruding pins (sometimes referred to as a bed of nails) are arranged facing a second flat layer whereby electromagnetic waves can propagate in a space between the first and second layer. This layout has proven to be associated with many benefits, including offering better performance (e.g. lower leakage) and being easy to manufacture.

For example, in international application with publication number WO2021/251866 a multi-layer waveguide with a metasurface comprising thick and thin structures forming a metasurface is presented. This type of waveguide can be made much thinner than conventional waveguides which makes the waveguide cheaper to produce and more compact while still offering excellent radiation performance. However, a problem with all waveguide or transmission line types emerges at the interface between one waveguide or transmission line coupled to another waveguide or transmission line or at the interface between an electronic component (e.g. a transmitter of receiver) and a waveguide or transmission line. It is challenging to achieve low reflection levels and insertion loss levels at different interfaces even in a lab environments, and for large scale manufacturing the problem is worsened by increased manufacturing tolerances. It is especially difficult to achieve a transition with good performance for the thin multi-layer waveguides mentioned in the above. Design of well performing transitions for this new, very thin, multi-layer waveguide design has proven to be non-trivial meaning that some multi-layer waveguide designs are underutilized to the challenges associated with feeding/extracting electromagnetic signals from these structures.

### GENERAL DISCLOSURE OF THE INVENTION

It is a purpose of the present invention to overcome at least some of the shortcomings of the prior solutions mentioned in the above and specially to overcome the shortcomings of transitions for multi-layer waveguides with very thin layers.

According to a first aspect of the invention there is provided a multi-layer waveguide transition comprising at least three physical layers in a stacked configuration, the at least three physical layers comprising: a top layer, at least one intermediate layer, and a bottom layer. A bottom side of the top layer is arranged to face a top side of the at least one intermediate layer and a top side of the bottom layer faces a bottom side of the at least one intermediate layer, wherein the at least one intermediate layer comprises an elongated waveguide channel extending along an elongation axis having a guiding portion and a coupling portion. A metasurface is arranged between the bottom side of the top layer and the top side of the at least one intermediate layer and between the top side of the bottom layer and the bottom side of the at least one intermediate layer to surround the elongated waveguide channel, wherein the bottom layer is provided with a port opening which overlaps with the coupling portion of the elongated waveguide channel, and wherein the elongated waveguide channel is provided with a central conductor arranged within the guiding portion and extending at least partially into the coupling portion.

With the metasurface being arranged between the bottom side of the top layer and the top side of the at least one intermediate layer it is meant that at least one of the bottom side of the top layer and top layer of the at least one intermediate layer is provided with a metasurface. The same applies also for the metasurface arranged between the bottom side of the at least one intermediate layer and the top side of the bottom layer.

The metasurface comprises a plurality pins arranged on the surface in a regular or irregular (e.g. random) pattern. The pins form thick and thin sections with each pin constituting a thick section and the space between pins constituting thin sections. For example, the thick sections protrude from the thin sections to have a height corresponding with the rest of the layer whereas the thin sections are arranged lower than the rest of the layer. That is, the metasurface may be formed as debossing of the surrounding surface.

The difference in height between thick sections and thin sections is less than one quarter of an operational wavelength. Preferably, the difference in height is less than one fifth, one sixth, one eighth or one tenth of an operational wavelength. In some implementations, the difference in height is even less than one fifteenth or one twentieth of the operational wavelength. This allows each layer of the multi-layer waveguide to be made very thin which makes the waveguide compact, cheap to produce while enabling some manufacturing techniques which otherwise would not have been possible to use, such as stamping or chemical etching.

In some implementations, the height difference between the thick and thin sections is 30-80% of the layer's thickness, such as 50-70% of the layer's thickness.

Additionally, this multi-layer waveguide does not necessitate that the individual layers are arranged in electrical contact. The layers may e.g. be arranged with a small separation from each other as an alternative to the layers being stacked and in electrical and physical contact with each other. Preferably, the layers are arranged close to each other, such as within one quarter of an operational wavelength. More preferably, the layers are arranged within one fifth, one sixth, one eighth or one tenth of an operational wavelength from each other.

The present invention is at least partially based on the understanding that with a multilayer metasurface structure and a central conductor which extends into the coupling portion the insertion loss and reflection of any electromagnetic waves transmitted out of or into the port opening is greatly reduced. Consequently, a space efficient and high performance transition between the port opening (which e.g. is coupled to a rectangular waveguide or arranged in close proximity to a transmitting/receiving patch) and central conductor waveguide extending in multi-layer waveguide is provided. This transition has surprisingly proven to be well suited for very thin multi-layer waveguide designs with metasurfaces with sub-quarter-wavelength textures. Accordingly, the problem of providing a high performance transition for very thin multi-layer waveguide designs is solved, allowing this type of multi-layer waveguides to be coupled to a wide range of other types of waveguide structures, such as rectangular waveguides or microstrip waveguides.

With this layered structure the waveguide is easy to manufacture (e.g. the layers can be manufactured separately) and becomes very compact while still providing high performance in terms of low leakage. Accordingly, the transition is well suited to be used in an antenna- or RADAR-device used in a road-vehicle.

In some implementations, the guiding portion of the elongated waveguide channel extends away from the coupling portion in at least two different directions so as to form a first guiding portion and a second guiding portion with a common coupling portion, and wherein each of the first and second guiding portions comprises a respective suspended central conductor extending at least partially into the common coupling portion.

Accordingly, a transition is provided which splits the electromagnetic waves entering into the port opening into two parts. For instance, this embodiments acts as a power splitter which e.g. may be used to fed two or more antennas.

In some implementations, each central conductor and/or the elongated waveguide channel is wider in the coupling portion compared to in the guiding portion.

A central conductor and/or elongated waveguide opening which is wider in the coupling portion compared to in the waveguiding portion has proven to facilitate better matching performance (e.g. reduced losses and reflections).

In some implementations, the central conductor enters the coupling portion along a first axis and wherein the central conductor comprises a transverse element extending along a second axis substantially perpendicular to the first axis, wherein the transverse element is connected to the at least one intermediate layer at opposite ends of the elongated waveguide channel at the coupling portion.

For example, the central conductor is T-shaped and is connected to both opposite sides of the elongated waveguide opening.

A central conductor with a transverse element in the coupling portion is associated with multiple benefits. Firstly, the coupling performance is enhanced. Secondly, the structural rigidity of the central conductor is enhanced which is important since the central conductor may be formed together with at least one intermediate layer and be very thin and fragile, making it susceptible to bending effects if the multi-layer waveguide is subject to acceleration or vibrations.

In some implementations, the at least one central conductor enters the coupling portion from an entry side and wherein there is an air gap between the end of central conductor and an opposing side of the coupling portion, the opposing side being opposite to the entry side.

With an air gap, the coupling properties are enhanced. In some embodiments a supporting stub is arranged in air gap, dividing the air gap into two portions.

In some implementations, the elongated waveguide channel comprises an intermediate portion, between each guiding portion and the coupling portion, wherein the width of each central conductor in the intermediate portion is different from the width in the respective guiding portion and in the coupling portion.

The inventors have realized that with a varying width in an intermediate portion of the central conductor the impedance matching of the transition is enhanced, resulting in lower insertion loss and reflections.

In some implementations each central conductor is provided with intermittently arranged supporting stubs connecting each central conductor to the at least on intermediate layer.

The supporting stubs provide structural integrity to the central conductor which is arranged or “suspended” elongated waveguide opening by the supporting stubs. Preferably, the supporting stubs alternate between being on either side of the central conductor. The supporting stubs are also preferably thin, e.g. having a width which at most half, or more preferably at most one quarter, of the width of the central conductor. In this way, the effect of the supporting stubs on the signal propagation properties is mitigated.

According to a second aspect of the invention there is provided an electromagnetic waveguide component comprising the multi-layer waveguide transition according to first aspect of the invention and a printed circuit board (PCB). The PCB comprises an active component connected to a transmitting and/or receiving element configured to transmit and/or receive electromagnetic waves and the PCB is configured to be mounted below a bottom side of the bottom layer, opposite to the top side, such that the transmitting and/or receiving element is arranged in electromagnetic communication with the opening port. The PCB may be mounted directly against the bottom layer or the PCB may be mounted against a spacing element that is located between the PCB and the bottom layer. The spacing element may in turn be provided with one or more recesses or through openings facing the PCB, the recesses or through openings being configured to house components protruding from the PCB. Since the bottom side of the bottom layer may be substantially or entirely flat the spacing element may provide enhanced structural stability and/or thermal contact between the bottom layer and the PCB components.

This electromagnetic waveguide component can be made very compact by allowing the PCB to mounted directly against the bottom layer.

In some implementations the transmitting and/or receiving element is arranged externally of the active component or wherein the transmitting and/or receiving element is integrated into a same package as the active component, forming a launcher in package component.

In some implementations, the active component is configured to be arranged in thermal contact with the bottom layer and optionally configured to be arranged in thermal contact with the bottom layer via a thermal pad arranged between the bottom layer and the active component.

A benefit associated with placing the active component in thermal contact with the bottom layer is that dissipated heat from the PCB will be transferred to the multi-layer waveguide transition which provides a cooling for the PCB. In some implementations, the layers are at least partially (e.g. coated), or wholly, made of metal which is a good thermal conductor. The waveguide transition will thus double as a heatsink and an electromagnetic waveguide.

While a thermal pad has some benefits (such as being rigid to enhance structural stability) other means for bringing the active component into thermal contact with the bottom layer could be used, such as a thermal paste or heat-pipe.

In some implementations, a spacing element is arranged between the PCB and the bottom layer, wherein the spacing element is provided with an opening configured to allow the active component or thermal pad to come into thermal contact with the bottom layer.

With a spacing element, a predetermined separation distance between the bottom side of the bottom layer and PCB can be obtained. This e.g. allows selection of a suitable heat pad, or allows holding the bottom layer in immediate contact with the active component. That is, the bottom layer and the PCB are placed at a desired separation distance and held together using the same component (spacing element) which makes the manufacturing process simple and efficient. In some implementations, the spacing element has at least one attachment pin configured to be melted or compressed and at least a tip portion of the attachment pin is configured to pass through the bottom layer. Accordingly, the attachment pins can be melted or compressed from the upper side of the bottom layer making the spacing element fixated to the bottom layer.

In some implementations, a metasurface is arranged between a top side of the PCB and the bottom side of the spacing element and/or between the bottom side of the bottom layer and a top side of the spacing element.

With a metasurface arranged between the PCB and the spacing element and/or between the spacing element and the bottom layer electromagnetic wave propagation is enhanced between the PCB and the waveguide transition due to e.g. lower losses.

According to a third aspect of the invention there is provided an inter-waveguide transition comprising a multi-layer waveguide transition according to the first aspect of the invention forming a first waveguide transition with a first port opening in its top layer. The inter-waveguide transition further comprising a second top layer and a second at least one intermediate layer, wherein a bottom side of the second top layer faces a top side of the at least one second intermediate layer and wherein the at least one second intermediate layer comprises a second elongated waveguide channel extending along an elongation axis having a second guiding portion and a second coupling portion. A metasurface is further arranged between the bottom side of the second top layer and the top side of the at least one second intermediate layer and a metasurface is arranged between the bottom side of the second at least one intermediate layer and a top side of the top layer. Additionally, the second elongated waveguide channel is provided with a central conductor arranged within the second guiding portion and extending at least partially into the second coupling portion and the first port opening is arranged in electromagnetic communication with the second coupling portion of the at least one second intermediate layer.

That is, while the waveguiding portion of the waveguide transition can be configured to follow any two-dimensional path within the extent of the stacked layers the inter-waveguide transition formed by a multi-layer waveguide transition in combination with a second top layer and a second intermediate layer enables the signal to be led also in a direction perpendicular to the layers, e.g. between two multi-layer waveguides.

In some implementations, the inter-waveguide transition further comprises a second bottom layer, wherein the metasurface is arranged between the bottom side of the second at least one intermediate layer and a top side of the top layer and/or is arranged between the second bottom layer and the at least one second intermediate layer. Wherein the second bottom layer is provided with a second port opening, and the first port opening and second port opening are arranged to overlap.

Accordingly, two separate waveguide transitions can be combined to form an inter-waveguide transition.

In some implementations, each port opening is slit shaped with two connected elongated slit portions extending along a respective slit port axis, and wherein the slit portion axes form an angle of between 10 and 80 degrees, or preferably between 25 and 65 degrees or most preferably about 45 degrees.

With slit portions that are angularly offset from each other the coupling between the multi-layer waveguide transitions is facilitated.

According to a fourth aspect of the invention there is provided a waveguide T-junction, comprising at least three physical layers in a stacked configuration. The at least three physical layers comprising a top layer, at least one intermediate layer, and a bottom layer. Wherein a bottom side of the top layer faces a top side of the at least one intermediate layer and a top side of the bottom layer faces a bottom side of the at least one intermediate layer. Additionally, the at least one intermediate layer comprises an elongated waveguide channel comprising a first portion extending along a first axis from a first end to a second end, and a second portion, connected to the first portion at a junction located between the first and second ends of the first portion and extending along a second axis to a third end, wherein the second axis is substantially perpendicular to the first axis. A metasurface is arranged between the bottom side of the top layer and the top side of the at least one intermediate layer and between the top side of the bottom layer and the bottom side of the at least one intermediate layer to surround the elongated waveguide channel. Also, the elongated waveguide channel is provided with a central conductor suspended in the first and second portion, wherein a width of the first portion of the central conductor is tapered at the junction such that the width of the central conductor decreases from the first end towards the junction and from the second end towards the junction.

That is, the waveguide junction may act as a low-profile power splitter/power combiner confined to the multi-layer waveguide. Accordingly, the junction can be made very thin and compact.

In some implementations, the first portion of the central conductor has a distal side and a proximal side, the proximal side being closer to the third end, and wherein the second portion of the central conductor is connected to the proximal side of the first portion of the central conductor. The distal side of the second portion of the central conductor tapers towards the proximal side at the junction and/or the width of the second portion of the central conductor increases from a first width to a second width at the connection to the proximal side of the second portion of the central conductor.

It is understood that the tapering and/or the width increase from the first to the second width can be continuous or stepwise. A tapering distal side and/or width increase has proven to facilitate coupling and mitigate loss, reflections etc.

In some implementations of the first, second, third or fourth aspect of the invention, the metasurface comprises thick sections and thin sections wherein a difference in height between thick sections and thin sections is less than the wavelength at an operational frequency divided by five, preferably less than the wavelength divided by eight, and most preferably less than the wavelength divided by ten.

This enables the waveguides to made very thin and compact.

Any features or benefits described in connection to the first aspect of the invention shares the same features or benefits with the intention according to the second, third or fourth aspect.

### BRIEF DESCRIPTION OF THE DRAWINGS

Aspects of the present invention will be described in more detail with reference to the appended drawings, showing currently preferred embodiments.

FIG. 1a depicts an exploded view of a multi-layer waveguide transition according to some implementations.

FIG. 1b is a top-view of the bottom layer with the central conductor of the intermediate layer of a multi-layer waveguide transition according to some implementations.

FIG. 1c is a perspective view of the bottom layer of a multi-layer waveguide transition according to some implementations.

FIG. 2 shows a top view of the bottom layer with a central conductor of the intermediate layer of a multi-layer waveguide transition with a bend according to some implementations.

FIG. 3 is a perspective view of an assembled multi-layer waveguide transition according to some implementations.

FIG. 4a shows a top view of the bottom layer with a central conductor of the intermediate layer of a multi-layer waveguide transition with a power splitting function according to some implementations.

FIG. 4b is a perspective view of a multi-layer waveguide transition with a power splitting function with the top layer lifted according to some implementations.

FIG. 5a is an exploded view of an inter-waveguide transition according to some implementations.

FIG. 5b shows a top view of the bottom layer with a central conductor of the intermediate layer of one multi-layer waveguide in an inter-waveguide transition according to some implementations.

FIG. 5c shows a cross-sectional perspective view of an inter-waveguide transition according to some implementations.

FIG. 6a shows a cross-sectional view of an electromagnetic waveguide component according to some implementations.

FIG. 6b shows a cross-sectional view of the bottom layer provided with openings according to some implementations.

FIG. 6c is a top-down view of a PCB with an active component connected to a plurality of transmitting and/or receiving elements according to some implementations.

FIG. 6d is a perspective view of a bottom side of a spacing element according to some implementations.

FIG. 6e is a perspective view of a top side of the spacing element according to some implementations.

FIG. 7a shows the bottom layer and the central conductor of the intermediate layer of a waveguide junction according to some implementations.

FIG. 7b is a perspective view of the waveguide junction with the top layer lifted, according to some implementations.

FIG. 8a is a cross-sectional view of a multi-layer waveguide with one intermediate layer according to some implementations.

FIG. 8b is a cross-sectional view of a multi-layer waveguide with three intermediate layers according to some implementations.

### DETAILED DESCRIPTION

In the following detailed description, preferred embodiments of the present invention will be described. However, it is to be understood that features of the different embodiments are exchangeable between the embodiments and may be combined in different ways, unless anything else is specifically indicated. Even though in the following description, numerous specific details are set forth to provide a more thorough understanding of the present invention, it will be apparent to one skilled in the art that the present invention may be practiced without these specific details. In other instances, well known constructions or functions are not described in detail, so as not to obscure the present invention.

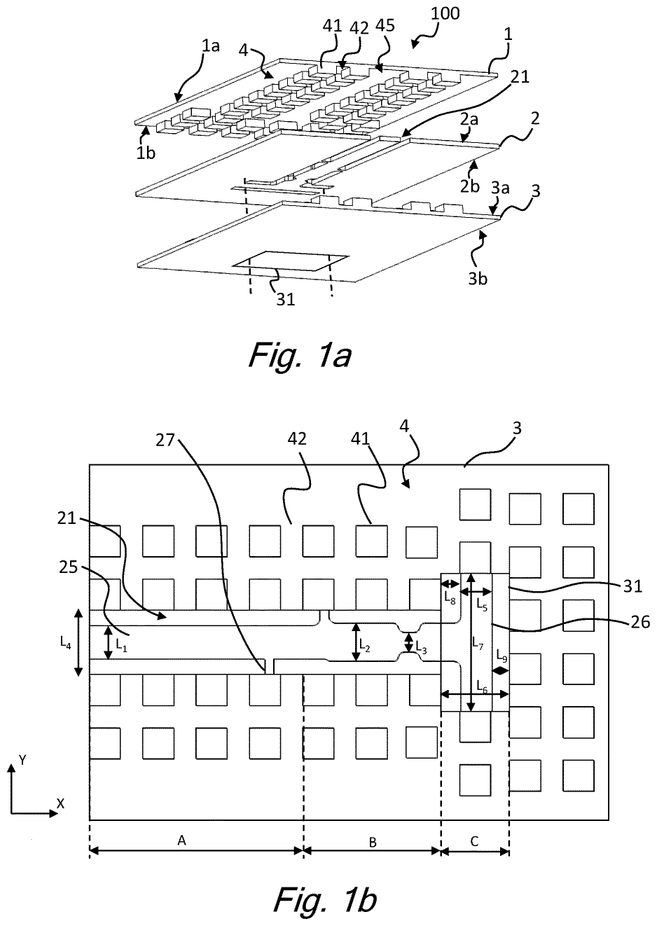

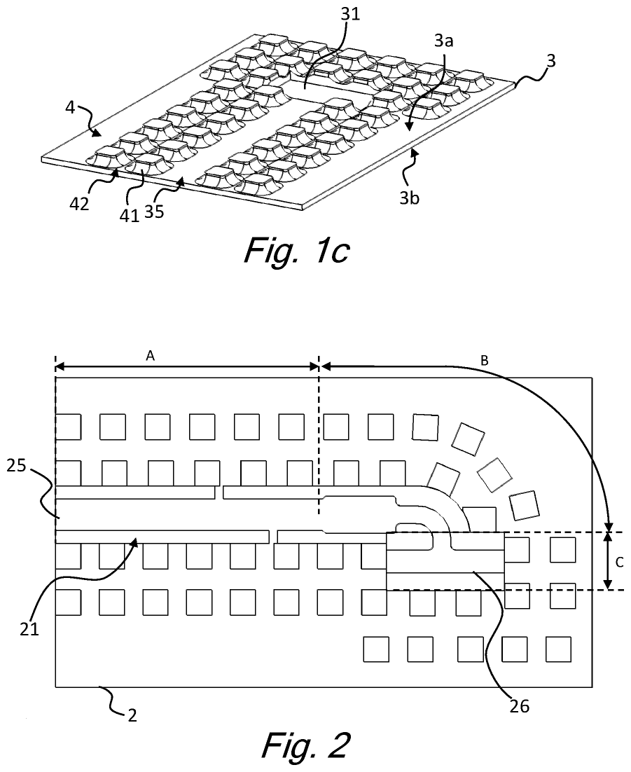

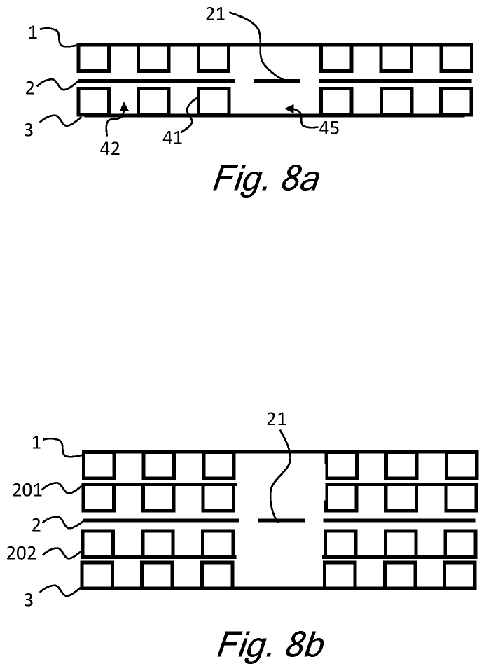

FIG. 1a depicts a multi-layer waveguide 10 according to some implementations. The multi-layer waveguide 10 comprises three physical layers 1, 2, 3, namely a top layer 1, at least one intermediate layer 2, and a bottom layer 3. In the embodiment depicted in FIG. 1a, there is only one intermediate layer 2 which enables a compact design. However, as will be described in the below in connection to FIG. 8b, there may be two or more intermediate layers 2.

In some implementations, the top layer 1 and bottom layer 3 are thicker than the at least one intermediate layer 2. For instance, the top and bottom layer 1, 3 are between 300 μm and 500 μm thick whereas the at least one intermediate layer 2 is between 50 μm and 200 μm thick, such as about 100 μm thick. The above exemplary thicknesses are suitable for simple and cost effective manufacturing but are merely exemplary and can vary outside of these ranges, e.g. depending on the operational frequency. The above exemplary thicknesses are suitable for 77 GHz operational frequency.

Each layer 1, 2, 3 may individually be made of a single piece of metal. All layers 1, 2, 3 may be made of the same metal or it is envisaged that at least one layer is made of a first metal whereas at least one other layer is made of a second, different metal. In some implementations, the top and bottom layers 1, 3 are made of a first metal whereas the at least one intermediate layer 2 is made of a second different metal. For example, the top and bottom layers 1, 3 are made of brass while at least one intermediate layer 2 is made of copper. As most losses will occur in the at least one intermediate layer 2 it is preferable to use the metal with the highest conductivity for in the at least one intermediate layer 2 whereas the top and bottom layers 1, 3 can be made of a cheaper less conductive material, such as brass. In addition to brass and copper, another metal that is suitable for making the layers 1, 2, 3 is aluminum.

In some implementations, at least one layer 1, 2, 3 is made from a non-metal material (e.g. a dielectric material such as a plastic or other polymer based material) and coated with a thin outer layer of metal (e.g. brass, copper or aluminum). The layers 1, 2, 3 may be coated on both the top sides 1a, 2a, 3a and bottom sides 1b, 2b, 3b. It is also envisaged that a layer 1, 2, 3 is coated on only one side. For example, for the top and bottom layers 1, 3 it is envisaged that only the bottom and top sides, respectively, that face another layer, meaning that these layers may be coated only on the sides facing another layer.

A metasurface 4 is arranged between the bottom side 1b of the top layer 1 and the top side 2a of the at least intermediate layer 2 and a metasurface 4 is arranged between the top side 3a of the bottom layer 3 and the bottom side 2b of the at least one intermediate layer 2. In the embodiment shown in FIG. 1a the metasurface 4 is arranged on the top surface 3a of the bottom layer 3 facing a flat surface at the bottom side 2b of the at least one intermediate layer 2 and on the bottom surface 1b of the top layer 1 facing a flat surface at the top side 2a of the at least one intermediate layer 2. Alternatively, the metasurface 4 is arranged on the bottom surface 2b of the at least one intermediate layer facing a flat surface at the top side 3a of the bottom layer and/or at the top surface 2a of the at least one intermediate layer 2 facing a flat surface at the bottom of the top layer 1.

In other words, many arrangements of the metasurface 4 are possible. Preferably, every interface between two layers is provided with a metasurface 4 on at least one of the layers. More preferably, each metasurface faces a flat portion of a neighboring layer meaning that there is only one metasurface arranged between two neighboring layers. In general, the metasurface 4 is a repeating or random structure forming an electromagnetic band gap (EBG) structure that prohibits electromagnetic waves from propagating in the space between the layers 1, 2, 3. The metasurface 4 can be defined by a plurality of negative layer volumes, such as an array of through-holes in the layer surrounding the elongated channel or a plurality of positive layer volumes such as a plurality of pins surrounding the elongated channel. In FIG. 1, the metasurface is realized as pins however a plurality of through holes could also be used, as explained in detail in international application published as WO2019/083439, hereby incorporated by reference in its entirety.

The metasurface 4 comprises a plurality of thick sections 41 (i.e. pins) and thin sections 42 arranged in a regular or irregular pattern. In FIG. 1a the shape of the pins is substantially square however this shape is merely exemplary and many different shapes are envisaged. For example, the pins may be circular, elliptical, triangular, hexagonal or any polygonal shape. Additionally, while the pins 41 are depicted with a flat top surface it is envisaged that the pins are provided with a rounded top, or a conical or pyramidal top. In some implementations, each surface that has a metasurface has a flat portion surrounding the metasurface and wherein the thick sections have a thickness corresponding to the layer thickness at the flat portion and the thin sections have a thickness that is less than the thickness at the flat portion. For example, each layer is made out of a sheet material with a thickness corresponding to the flat portion and the metasurface 4 is created by etching out thin sections 42, forming the thick sections 41 there between.

The at least one intermediate layer 2 is provided with an elongated channel 21 (also referred to as an elongated channel or opening). The elongated channel 21 defines a waveguide together with the top and bottom layers 1, 3. In some implementations, this is achieved with by providing an intermission 45 in the metasurface 4 corresponding to the elongated channel 21. The intermission 45 may be channel, such as a flat section, without metasurface 4 structures following the elongated channel 21. The metasurface 4 prohibits electromagnetic waves from propagating into the vertical space between the layers 1, 2, 3 meaning that the electromagnetic waves are confined to propagate along the elongated waveguide channel. As seen in FIG. 1a, the metasurface 4 is arranged to surround the elongated channel 21 which achieves this confinement of the electromagnetic waves.

Additionally, the bottom layer 3 is provided with a port opening 31 which overlaps with at least a portion of the coupling portion of the waveguide channel 21.

In FIG. 1b a top-down view of the bottom layer 3 is shown with elements of the at least one intermediate layer 2 superimposed on the bottom layer 3. The at least one intermediate layers is provided with a central conductor 25 arranged in the elongated channel 21. The central conductor 25 may be suspended in the elongated channel 21 supported by supporting stubs 27 connecting the intermediate layer 2 with the central conductor 25. For example, the central conductor 25 is formed by etching, stamping or otherwise removing material from the at least one intermediate layer 2 to form the suspended central conductor 25. The central conductor 25 arranged inside the elongated waveguide channel forms a coaxial waveguide.

The bottom layer 3 also comprises a port opening 31 which overlaps with at least a portion of the elongated channel 21 and the central conductor 25. The port opening 31 is where the waveguide is connected to an external device (e.g. another waveguide or a transmitting and/or receiving element). The port opening 31 is surrounded with the metasurface 4 to prohibit electromagnetic waves from leaking from the waveguide. The port opening 31 in the bottom layer 3 overlaps at least partially with the elongated channel 21. For example, a part of the elongated channel 21 is configured to match the port opening 31 in a normal projection relative the layers 3.

Similarly, the central conductor 25 also extends so as to at least partially overlap with the port opening 31. In the embodiment shown in FIG. 1b, the central conductor 25 comprises a transverse element which spans the part of the elongated channel 21 which overlaps with the port opening 31. The transverse element 26 and the central conductor 25 may form a T-shape.

Also depicted in FIG. 1b is an embodiment wherein the width of the central conductor 25 varies along its extension to e.g. enable better matching and transition performance.

The elongated channel 21 comprises a waveguiding portion A wherein the width L₁ of the central conductor 25 is constant. The width L₄ of the elongated channel 21 is larger than the width L₁ of central conductor 25 meaning that the central conductor 25 can be arranged inside the elongated channel 25, separated on either side from the rest of the at least one intermediate layer. Optionally, there is one or more support stubs 27 supporting the central conductor 25 in the waveguiding portion A.

The elongated channel 21 further comprises a coupling portion C which at least partially (or completely) overlaps with the port opening 31 of the bottom layer. In the embodiment shown, the coupling portion C of the elongated channel 21 has a width of L₇, which is greater than the width L₄ in the waveguiding portion A, and a length of L₆. The width of the central conductor 25 also increases from L₁ in the waveguiding portion A to L₇ in the transverse element 26 of the central conductor 25 arranged in the coupling portion C.

To achieve good coupling properties, it is beneficial if some void space is left in the elongated channel 25 in the coupling portion C. As shown in FIG. 1b, there is an air gap L₉ between the transverse element 26 and the far end of the elongated channel 21. Optionally, a supporting stub 27 can be arranged in the air gap L₉ as this may facilitate structural stability. Similarly, there is an air gap L₈ between the outer ends of the transverse element 26 and the near side of the elongated channel 21. The central conductor 25 enters the coupling portion from the near side and extends towards the far end which is opposite the near side.

While a transverse element 26 forming a T-shaped central conductor overhanging the port opening 31 facilitates good transition performance it is envisaged that many other shapes of the central conductor 25 at the coupling portion C are possible. Regardless of the shape used in the coupling portion C there may be an issue of providing sufficient impedance matching between the waveguiding portion A and the coupling portion C to avoid reflections and excessive insertion losses.

To this end, there is in some implementations provided an intermediate portion B between the waveguiding portion A and the coupling portion C of the elongated channel 21. In the intermediate portion B the width of the central conductor 25 is varied to facilitate impedance matching between the waveguiding portion A and the coupling portion C. In the shown implementation, the width of the central conductor 25 in the intermediate portion B varies from the first width L₁ to a second width L₂, to a third width L₃, and back to the second width L₂ as the central conductor 25 approaches the coupling portion C.

The first width L₁ is the width of the central conductor 25 in the guiding portion A, the second width L₂ is the width of the central conductor 25 entering into the coupling portion 25 and the third width L₃ is smaller than both the first width L₁ and the second width L₂. In some implementations, the second width L₂ is greater than the first width L₁. However, it is understood that these width arrangements and variations in the intermediate portion B are merely exemplary, and that many other width arrangements are possible.

With further reference to FIG. 1c there is depicted a perspective view of the bottom layer 3. The bottom layer 3 is provided with an port opening 31 arranged to overlap at least partially with the elongated channel 21. The port opening 31 extends through the bottom layer 3, from the top side 3a to the bottom side 3b. The metasurface 4 comprising the thick sections 41 and thin sections 42 are here arranged on the top side 3a of the of the bottom layer 3 so as to face the at least one intermediate layer. Alternatively, the top side 3a of the bottom layer 3 is flat and the metasurface 4 is arranged on the bottom side of the at least one intermediate layer. A region 35 of the bottom layer 3 is devoid of the thick sections 42 of the metasurface. The region 35 is configured to overlap with the elongated channel of the at least one intermediate layer. In this way, the metasurface 4 will surround the elongated channel and form a waveguide.

The top layer may be identical to the bottom layer 3 except that that no port opening 31 is provided and that the top layer is flipped relative to the bottom layer 3, such that the metasurface 4 of the top layer faces the top side of the at least one intermediate layer.

FIG. 2 shows a top view of an intermediate layer 2 with a curved elongated channel 21 and a curved central conductor 25. In the depicted embodiment, a 90 degree bend is provided in the intermediate portion B of the elongated channel 21, however, the bend may be provided at another place along the elongated channel 21, e.g. in the waveguiding portion A. The width of the central conductor 25 may vary as described in connection to FIG. 1b in the above regardless of a bend being provided in the intermediate section B.

With one or more bends or curves provided in the elongated channel 21 it is possible arrange the coupling portion C, the transverse element 26 and the port opening in the bottom layer freely while still guiding electromagnetic signals to/from the coupling portion C in any desired direction parallel to the layers forming the waveguide.

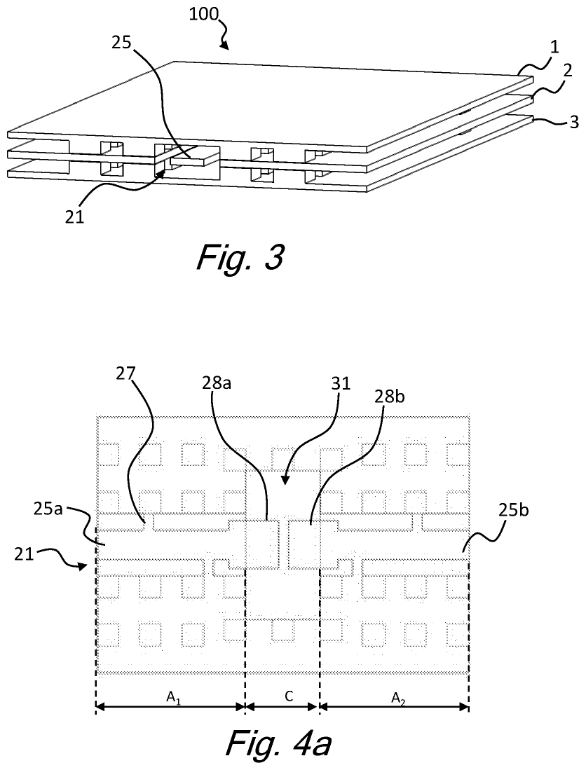

FIG. 3 shows a perspective view of a waveguide transition 10 comprising a top layer 1, an intermediate layer 2 and a bottom layer 3. The bottom layer 3 is provided with an port opening (not shown) through which electromagnetic signals can enter into the waveguide. The electromagnetic signals propagate in a direction parallel to the layers 1, 2, 3 along the elongated channel 21. The elongated channel is also provided with a central conductor 25 suspended in the intermediate layer 2 making the waveguide a coaxial waveguide. Preferably, each metasurface is arranged to face a flat surface of an adjacent layer. In the embodiment depicted in FIG. 2 the intermediate layer 2 does not have any metasurface and is substantially flat on both the top and bottom side, wherein the top and bottom layers 1, 3 each comprises a metasurface facing the flat intermediate layer 2.

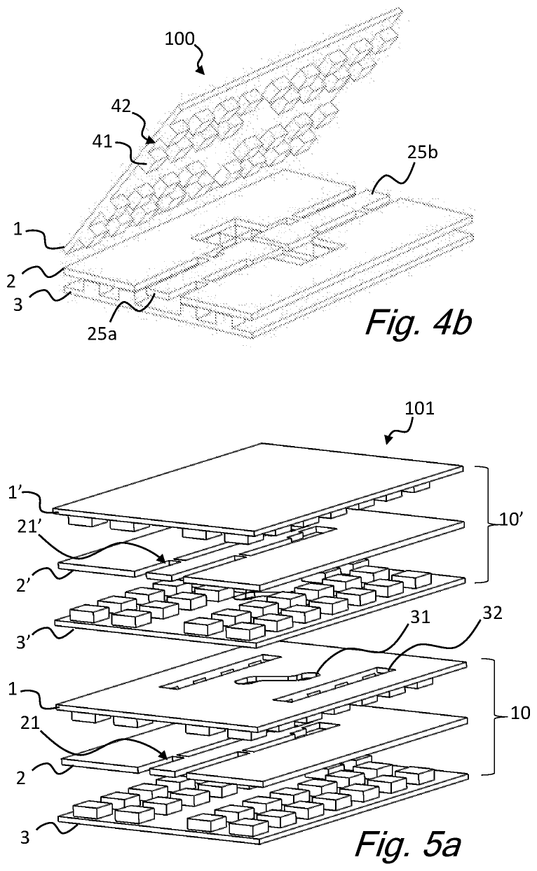

FIG. 4a depicts the intermediate layer 2 of a waveguide transition wherein the placement of the metasurface thick sections has been highlighted. The elongated channel 21 comprises a first and a second waveguiding portion A1, A2 extending away from a common coupling portion C. Each waveguiding portion A1, A2 comprises an individual central conductor 25a, 25b extending at least partially into the common coupling portion C of the elongated channel 21 which at least partially overlaps with an port opening 31 arranged in the bottom layer. The central conductors 25a, 25b are separated with an air gap in the common coupling portion C. In this way, the waveguide transition acts as a power splitter which splits electromagnetic signals entering through the port opening into two parts, each part propagating along each waveguiding portion A1, A2 respectively. Each central conductor 25a, 25b is preferably provided with a wide portion 28a, 28b which at least extends into common coupling portion C and optionally extends at least partially into the respective waveguiding portion A1, A2 or optional respective intermediate portions (not shown).

With further reference to FIG. 4b, the waveguide transition of FIG. 4a is shown in a perspective view with the top layer 1 lifted to show the intermediate layer 2 with the common coupling portion C and the respective waveguiding portions A1, A2 with respective central conductors 25a, 25b extending away from the common coupling portion C. The thick and thin sections 41, 42 forming the metasurface are arranged to surround the waveguiding portions A1, A2 and the common coupling portion C. The bottom layer 3 is provided with a port opening (not shown) where electromatic signals can enter/exit the waveguide transition, e.g. from/to a hollow waveguide such as a rectangular waveguide.

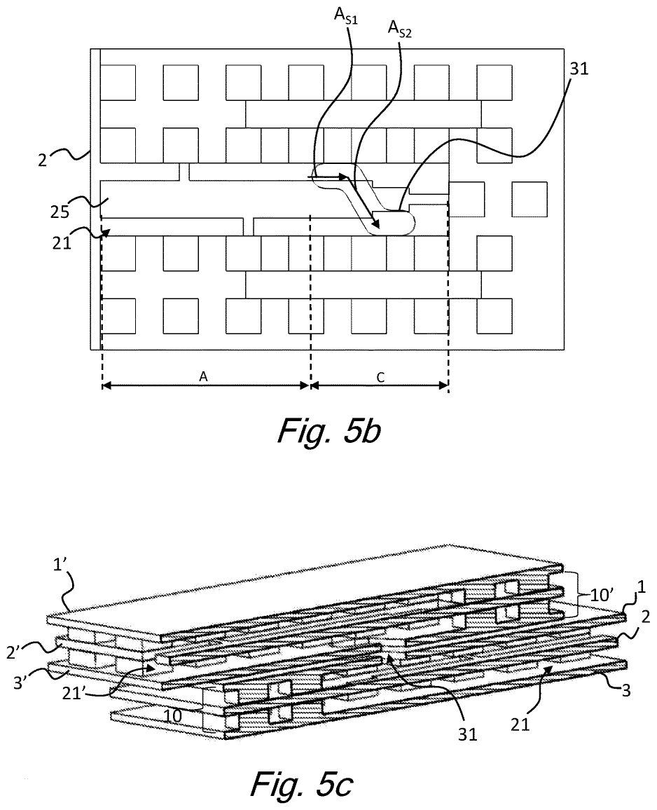

FIG. 5 shows an exploded view of an inter-waveguide transition 101 comprising a first wave guide transition 10 and a second waveguide transition 10′. Each of the first and second waveguide transitions 10, 10′ may be as presented in any of the embodiments described herein. Each waveguide transition 10, 10′ has a port opening 31 in the bottom layer 3′ and top layer 1, respectively and the waveguide transitions 10, 10′ are arranged with respect to each other such that the port openings 31 are in electromagnetic communication with each other. For instance, the port openings 31 are aligned with each other. The at least one intermediate layer of each waveguide transition 10, 10′ further comprises a respective elongated channel 21, 21′ and a central conductor extending in the elongated channel 21, 21′. The central conductor of each waveguide transition 10, 10′ extends so as to at least partially overlap with the port opening 31. In this way, electromagnetic signals propagating along the elongated channel of the first waveguide transition 10 can enter into the second waveguide transition 10′ via the communicating port openings 31 and then propagate along the elongated channel 21′ of the second waveguide transition 10′.

In some embodiments, the bottom layer 3′ of the second waveguide transition 10′, or the top layer 1 of the first waveguide transition 10, is omitted leaving one of the top layer 1 of the first transition 10 and the bottom layer 3′ of the second transition 10′ to act as a single layer separating the at least one intermediate layer 2, 2′ of each transition 10, 10′. That is, instead of a total of six layers 1, 2, 3, 1′, 2′, 3′ only five layers can be used to form an inter-waveguide transition 101 which makes for an even thinner inter-waveguide transition 101.

With further reference to FIG. 5b it is shown in a top view how the port opening 31 of the bottom layer 3 in the first waveguide transition 10 overlaps with the central conductor 25 extending in the elongated channel. The elongated channel has a waveguiding portion A and a coupling portion C wherein the coupling portion at least partially overlaps with the port opening 31. Similar to the embodiment described in FIG. 1b it has been found that by altering the width of the central conductor 25 in, or at least in the vicinity of, the coupling portion C the coupling properties between the two waveguide transitions are enhanced. When transitioning through the port opening 31 to another waveguide transition it has been found that the central conductor may be tapered (e.g. stepwise or continuously tapered) in the coupling portion from the width in the waveguiding portion A towards a narrower width in the coupling portion C. In the embodiment shown, at least some of the width reduction (e.g. a width reduction step) overlaps with the extension of the port opening 31.

The narrower central conductor in the coupling portion may connected to the far side of the elongated channel 21, the far side being opposite to the side at which the waveguiding portion A enters the coupling portion C. This enhances structural stability, however, it is also possible that the central conductor 25 does not contact the far side.

The port opening 31 are preferably elongated with at least one bend as this has been found to facilitate electromagnetic coupling between waveguide transitions 10, 10′. For example the first and second port openings 31 are shaped like elongated slits having at least a first elongated portion and a second elongated portion extending along a respective first slit portion axis A_{S1} and second slit portion axis A_{S2}. The slit portion axes, A_{S1}, A_{S2} forms an angle of between 10 and 80 degrees, or preferably between 25 and 65 degrees or most preferably about 45 degrees. With two or more slit portions many different slit shapes are possible, e.g. the port opening 31 between transitions 10, 10′ may be S-, Z- or C-shaped.

FIG. 5c depicts a cross-sectional perspective view of an intra-waveguide transition 101 according to some implementations. The inter-waveguide transition is similar to the inter-waveguide transition of FIG. 5a and FIG. 5b however in this implementations the elongated waveguide channels of the first and second waveguide transition 10, 10′ extend away from each other in different directions. In the inter-waveguide transition of FIG. 5a the electromagnetic signals propagating along the first elongated waveguide channel 21 in a first direction towards the port opening 31 will propagate through the port opening 31 and into the second elongated waveguide channel 21′ and then along a second direction opposite to the first direction. In the inter-waveguide transition of FIG. 5c, the electromagnetic signals propagating along the first elongated waveguide channel 21 in a first direction towards the port opening 31 will propagate through the port opening 31 and into the second elongated waveguide channel 21′ and continue to propagate the first direction. That is, the directions along which the elongated channels of the respective waveguides in an inter-waveguide transition extends may be the same or different. For example, each elongated waveguide channel 21, 21′ extends away from the port opening 31 along a respective axis, wherein the respective axes form an angle or about zero degrees (as shown in FIG. 5a) or about 180 degrees (as shown in FIG. 5c). Furthermore, it is envisaged that the elongated waveguide channels may be arranged in other ways as well, such that the respective axes form any angle between 0 and 360 degrees, such as about 45 degrees or about 90 degrees.

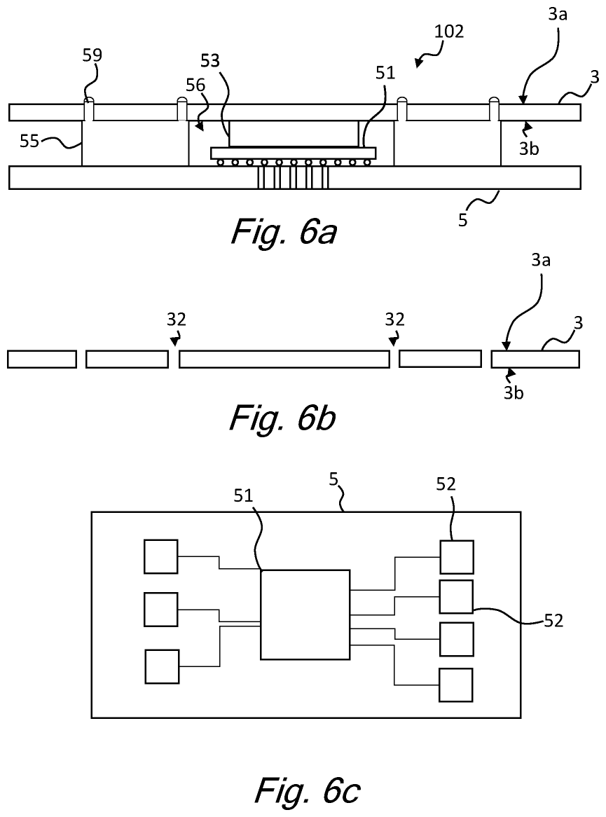

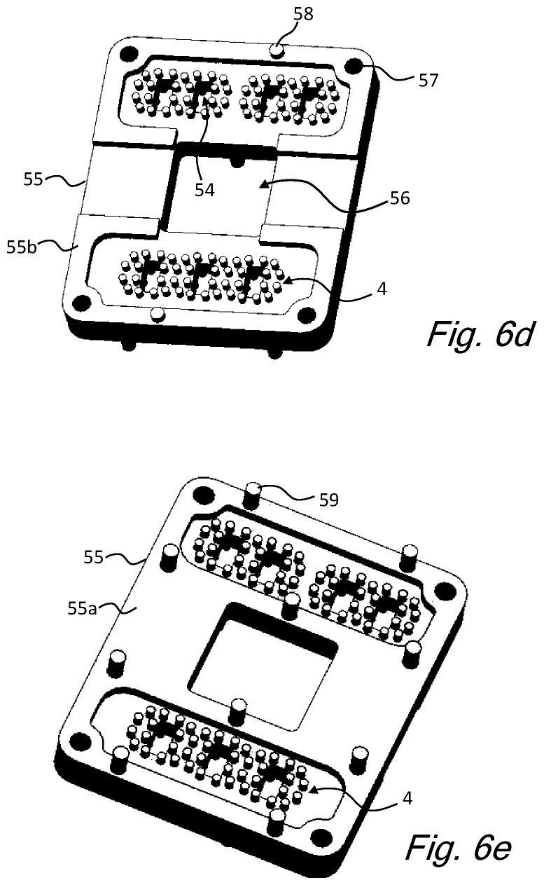

FIG. 6a depicts an electromagnetic component 102 according to some embodiments. The electromagnetic component comprises a waveguide transition and a PCB 5 arranged against the electromagnetic waveguide transition. In FIG. 6a the bottom layer 3 of the waveguide transition is shown and, optionally, there is a metasurface arranged on the top side 3a of the bottom layer 3. The bottom side 3b of the bottom layer 3 faces the PCB 5.

The PCB 5 further comprises an active component 51. The active component 51 may e.g. comprise at least one of an amplifier, a mixer, an active filter or a processor. The active component 51 emits heat which should be dissipated. It has been realized that since the layers 3 of the waveguide transition are metal layers, e.g. made as solid metal pieces or made of a non-metal layer covered with a metal these layers feature good thermal conductivity. To this end, the PCB 5 with the active component 51 is arranged in abutment against the bottom side 3b of the bottom layer 3 of the waveguide transition. In some implementations, the active component is provided with a heat pad 53 arranged on top of the active component 51 wherein the heat pad 53 bridges the gap between the active component 51 and the bottom layer 3 to bring these into thermal contact with each other. The heat pad 53 is typically made of a silicone material or a wax. The heat pad 53 may also be realized as a layer of thermal paste.

The PCB 5 and the bottom layer 3 may be attached to each other using a spacing element 55 which is arranged between the PCB 5 and the bottom layer 3 of the waveguide transition. In FIG. 6a, a cross-section of the spacing element 55 is shown where a through opening 56 is provided allowing the active component 51 and/or the heat pad 53 to contact the bottom layer 3. Additionally or alternatively, the spacing element 55 may comprise at least one through openings and/or recess so as to allow one or more additional components to be placed between the PCB 5 and the bottom layer 3. In some situations, each layer, including the bottom layer 3, is essentially flat on one side. Layers that are essentially flat have proven beneficial for manufacturing purposes, and with a spacing element it is still possible to house components protruding from the PCB 5 below the bottom layer 3.

In some implementations, the spacing element 55 is provided with attachment pins 59 that are configured to pass through the bottom layer 3. With further reference to FIG. 6b it shown that the bottom layer 3 may be provided with pin receiving holes 32 formed through the bottom layer 3 whereby the attachment pins 59 can be passed through the pin receiving holes 32 and the melted or compressed from the top side 3a of the bottom layer 3 to fasten the bottom layer against the spacing element 55 and the PCB 5.

FIG. 6c shows schematically a top view of a PCB 5 with an active component 51 connected to a plurality of transmitting and/or receiving elements 52 that are displaced from the active component along the PCB 5. The transmitting and/or receiving elements 52 may e.g. be patch antennas integrated onto the PCB 5 and electrically connected to terminals of the active component 51. Each transmitting and/or receiving element 52 is placed under an opening through opening arranged in the spacing element 55 and an opening port in the bottom layer 3 of the waveguide transition. In this way, electromagnetic signals transitioning from/to the transmitting and/or receiving element 52 into the elongated channel waveguide of the waveguide transition arranged on top of the PCB 5. At the same time, the waveguide transition acts as heatsink that dissipates some of the heat emitted by the active component 51. In this way, an electromagnetic component comprising both an active component 51 and a passive waveguide structures can be made very compact while still providing high coupling performance and heat dissipation capabilities.

In some implementations, the active component 51 is a “launcher in package” component comprising both active elements (e.g. amplifiers and/or a processor) and the transmitting/receiving elements.

FIG. 6d depicts a perspective view of the spacing element 55 according to some implementations. The spacing element 55 has a through opening 56 allowing the active component and/or thermal pad to come into direct contact with the bottom side of the bottom layer. The bottom side 55b of the spacing component 55 is configured to face the PCB when arranged between the PCB and the bottom layer. The PCB may be attached to the spacing element 55, e.g. via screws that are inserted from the backside of the PCB and engage screw holes 57 arranged in the bottom side of the spacing element 55. The spacing element 55 may also comprise a metasurface 4 surrounding any opening 54 arranged to confine electromagnetic waves propagating between the bottom layer and the PCB. Accordingly, the spacing element 55 may have a metasurface 4 arranged on one of the top side and the bottom side 55b to prevent electromagnetic waves leaking in directions parallel with the layers. The bottom side 55b of the spacing element 55 may also comprise at least two alignment pins 58 configured to cooperate with corresponding alignment slots in the PCB to ensure proper alignment of the spacing element 55 with respect to the PCB.

With reference to FIG. 6c and FIG. 6d is shown that the spacing element 55 comprises one opening 54 for each transmitting/receiving element 52 present on the PCB 5 with each opening being surrounded with a metasurface 4. In the example shown, the PCB 5 has three transmitting/receiving elements 52 on one side of the active component 51 and four transmitting/receiving elements 52 on the other side of the active component 51, accordingly the spacing element 55 has three openings and four openings one either side of the through opening 56, respectively, where the active component 51 is to be arranged in the through opening 56.

FIG. 6e shows the top side 55a of the spacing element 55. The top side 55a may also comprise a metasurface 4 surrounding elongated channels configured to confine electromagnetic radiations propagating to/from the PCB to/from the waveguide transition. FIG. 6e also shows the attachment pins 59 configured to pass through the bottom layer so as to fasten the bottom layer against the spacing element 55.

The spacing element may be made of a metal (for example copper, brass or aluminum) or made of a material which is coated with a metal layer. Additionally, the spacing element 55 may be much thicker compared to the thickness of the layers in the waveguide transition. Accordingly, the manufacturing tolerances of the spacing element 55 will in general be much coarser compared to the layers of the waveguide transition meaning that the metasurface 4 of the spacing element may be different (e.g. having a much larger height difference between thick and thin sections) with respect to the metasurface 4 of the waveguide transition layers.

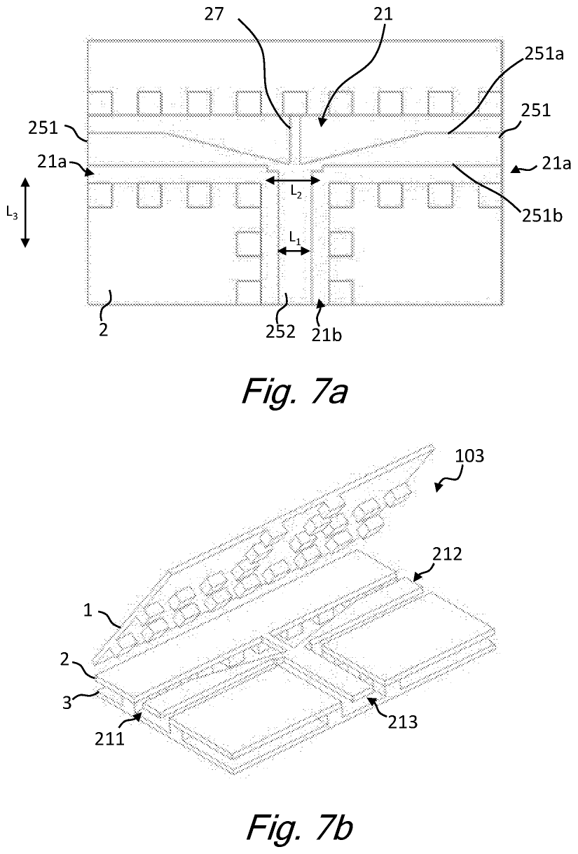

In FIG. 7a and FIG. 7b a multi-layer waveguide junction according to some embodiments is shown. The junction may be a T-junction with three input/output ports, a first port, a second port and a third port. The at least one intermediate layer 2 comprises an elongated channel with a first portion 21a that extends between the first and second port and a second portion 21b that connects to the first portion 21a at some point between the first and second port to form a three-way junction. Each portion of the elongated channel 21a, 21b further comprises a central conductor portion 251, 252 wherein the central conductor portions 251, 252 are connected at the junction, the first central conductor portion 251 extends along the first elongated channel portion 21a and the second central conductor portion 252 extends along the second elongated channel portion 21b.

The width of the second central conductor portion 252 may increase as it approaches the junction. For example, as shown in FIG. 7a, the central conductor width is L1 and increases to L2 wherein L2 is greater than L1 as the second central conductor portion 252 approaches the junction. This increase in width may facilitate coupling performance.

The first central conductor portion 251 comprises a distal side and a proximal side. The second central conductor portion 252 connects to the proximal side of the first central conductor portion 251. As the first central conductor portion 251 approaches the junction from the first port and from the second port the width of the first central conductor portion 251 decreases in a tapered fashion (e.g. tapers linearly). The tapering is only on the distal side meaning that the distance between the elongated channel perimeter and the central conductor increases on the distal side as the first central conductor portion 251 approaches the junction whereas this distance is constant on the proximal side.

In some implementations, the first central conductor portion 251 is further provided with a supporting stub 27 at the junction which facilitates structural stability.

The multi-layer waveguide junction may e.g. be used as a signal splitter and/or combiner. In FIG. 4a and FIG. 4b a waveguide transition acting as a splitter and/or combiner is shown, however with the waveguide junction shown in FIG. 7a and FIG. 7b an alternative splitter and/or combiner is shown. For instance, the waveguide junction can be connected to the waveguiding portion of the waveguide transition shown in FIG. 1a-c so as to form a waveguide system wherein the electromagnetic signals are combined and/or split a location which is offset from the port opening 31.

FIG. 8a depicts a cross-sectional view of a multi-layer waveguide with three layers, a top layer 1, an intermediate layer 2 and a bottom layer 3. The cross-sectional view shows the coaxial waveguide channel with the central conductor 21 arranged as a coaxial conductor. FIG. 8a and FIG. 8b also shows the metasurface comprising thick sections 41 and thin sections 42 as well as an intermission 45 in the metasurface forming a part of the coaxial waveguide.

FIG. 8b depicts a cross sectional view of a multi-layer waveguide with five layers, a top layer 1, three intermediate layers 2, 201, 202 and a bottom layer 3. In order from top to bottom the intermediate layers are arranged with intermediate layer 201 first, intermediate layer 2 second and intermediate layer 202 third. Each of intermediate layer 201 and 202 features a metasurface and that faces the intermediate layer 2 which is flat and does not comprise a meta surface. The top layer 1 has a metasurface on the bottom side, facing a flat upper side of intermediate layer 201 and the bottom layer 3 also has a metasurface arranged on the top side facing a flat bottom surface of intermediate layer 202.

More intermediate layers may be added as desired. Preferably, the space between each pair of neighboring layers is provided with at least one metasurface. More preferably, the space between each pair of neighboring layers is provided with only one metasurface wherein the metasurface faces a flat surface of the neighboring layer.

The person skilled in the art realizes that the present invention by no means is limited to the preferred embodiments described above. On the contrary, many modifications and variations are possible within the scope of the appended claims. For example, a multi-layer electromagnetic component may be connected to a waveguide junction and/or an inter-waveguide transition to form a waveguide system.

1.-20. (canceled)

21. A multi-layer waveguide transition comprising at least three physical layers in a stacked configuration, the at least three physical layers comprising:
a top layer,
at least one intermediate layer, and
a bottom layer,
wherein a bottom side of the top layer faces a top side of the at least one intermediate layer and a top side of the bottom layer faces a bottom side of the at least one intermediate layer,
wherein the at least one intermediate layer comprises an elongated waveguide channel extending along an elongation axis having a guiding portion and a coupling portion,
wherein a metasurface is arranged between the bottom side of the top layer and the top side of the at least one intermediate layer and between the top side of the bottom layer and the bottom side of the at least one intermediate layer to surround the elongated waveguide channel,
wherein the bottom layer is provided with a port opening which overlaps with the coupling portion of the elongated waveguide channel, and
wherein the elongated waveguide channel is provided with a central conductor arranged within said guiding portion and extending at least partially into the coupling portion.

22. The multi-layer waveguide transition according to claim 21, wherein the guiding portion of the elongated waveguide channel extends away from the coupling portion in at least two different directions so as to form a first guiding portion and a second guiding portion with a common coupling portion, and
wherein each of the first and second guiding portions comprises a respective suspended central conductor extending at least partially into the common coupling portion.

23. The multi-layer waveguide transition according to claim 21, wherein each central conductor is wider in the coupling portion compared to in the guiding portion.

24. The multi-layer waveguide transition according to claim 21, wherein the elongated waveguide channel is wider in the coupling portion compared to the guiding portion.

25. The multi-layer waveguide transition according to claim 21, wherein the central conductor enters the coupling portion along a first axis and wherein the central conductor comprises a transverse element extending along a second axis substantially perpendicular to the first axis, wherein the transverse element is connected to the at least one intermediate layer at opposite ends of the elongated waveguide channel at the coupling portion.

26. The multi-layer waveguide transition according to claim 21, wherein at least one central conductor enters the coupling portion from an entry side and wherein there is an air gap between the end of central conductor and an opposing side of the coupling portion, the opposing side being opposite to said entry side.

27. The multi-layer waveguide transition according to claim 21, wherein the elongated waveguide channel comprises an intermediate portion, between each guiding portion and the coupling portion, wherein the width of each central conductor in the intermediate portion is different from the width in at least one of the respective guiding portion and in the coupling portion.

28. The multi-layer waveguide transition according to claim 21, wherein each central conductor is provided with intermittently arranged supporting stubs connecting each central conductor to the at least on intermediate layer.

29. An electromagnetic waveguide component comprising:
the multi-layer waveguide transition according to claim 21, and
a printed circuit board, PCB, comprising an active component connected to a transmitting and/or receiving element configured to transmit and/or receive electromagnetic waves,
wherein the PCB is configured to be mounted below a bottom side, opposite to the top side, of the bottom layer such that the transmitting and/or receiving element is arranged in electromagnetic communication with the port opening, and
wherein the transmitting and/or receiving element is arranged externally of the active component or wherein the transmitting and/or receiving element is integrated into a same package as the active component, forming a launcher in package component.

30. The electromagnetic waveguide component according to claim 29, wherein the active component is configured to be arranged in thermal contact with the bottom layer via a thermal pad arranged between the bottom layer and the active component.

31. The electromagnetic waveguide component according to claim 29, further comprising a spacing element arranged between the PCB and the bottom layer, wherein the spacing element is provided with at least one through opening or recess configured to house at least one component extending from a top side of the PCB, the top side of the PCB facing a bottom side of the spacing element.

32. The electromagnetic waveguide component according to claim 31, wherein a metasurface is arranged between the top side of the PCB and the bottom side of the spacing element and/or between the bottom side of the bottom layer and the top side of the spacing element.

33. An inter-waveguide transition comprising:
a multi-layer waveguide transition according to claim 21, forming a first waveguide transition with a first port opening in its top layer,
a second top layer, and
a second at least one intermediate layer,
wherein a bottom side of the second top layer faces a top side of the at least one second intermediate layer,
wherein the at least one second intermediate layer comprises a second elongated waveguide channel extending along an elongation axis having a second guiding portion and a second coupling portion,
wherein a metasurface is arranged between the bottom side of the second top layer and the top side of the at least one second intermediate layer and a metasurface is arranged between the bottom side of the second at least one intermediate layer and a top side of the top layer,
wherein the second elongated waveguide channel is provided with a central conductor arranged within said second guiding portion and extending at least partially into the second coupling portion, and
wherein the first port opening is arranged in electromagnetic communication with the second coupling portion of the at least one second intermediate layer.

34. The inter-waveguide transition according to claim 33, further comprising a second bottom layer, wherein the metasurface arranged between the bottom side of the second at least one intermediate layer and a top side of the top layer is arranged between the second bottom layer and the at least one second intermediate layer, wherein the second bottom layer is provided with a second port opening, and the first port opening and second port opening are arranged to overlap.

35. The inter-waveguide transition according to claim 33, wherein each port opening is slit shaped with two connected elongated slit portions extending along a respective slit port axis, and wherein the slit portion axes form an angle of between 10 and 80 degrees, or preferably between 25 and 65 degrees or most preferably about 45 degrees.

36. The multi-layer waveguide transition according to claim 21, wherein the metasurface comprises thick sections and thin sections wherein a difference in height between thick sections and thin sections is less than the wavelength at an operational frequency divided by five, preferably less than the wavelength divided by eight, and most preferably less than the wavelength divided by ten.

37. The multi-layer waveguide transition according to claim 21, wherein at least one of the at least three physical layers is made of a metal material or made of a non-metal material covered with a metal layer, preferably each of the at least three physical layers, respectively, is made of a metal material or made of a non-metal material covered with a metal.

38. The multi-layer waveguide transition according to claim 37, wherein at least two physical layers of the at least three physical layers are made of or coated with a respective metal material, the respective metal materials being different metal materials.

39. A multi-layer waveguide T-junction, comprising at least three physical layers in a stacked configuration, the at least three physical layers comprising:
a top layer,
at least one intermediate layer, and
a bottom layer,
wherein a bottom side of the top layer faces a top side of the at least one intermediate layer and a top side of the bottom layer faces a bottom side of the at least one intermediate layer,
wherein the at least one intermediate layer comprises an elongated waveguide channel comprising a first portion extending along a first axis from a first end to a second end, and a second portion, connected to the first portion at a junction located between the first and second ends of the first portion and extending along a second axis to a third end, wherein the second axis is substantially perpendicular to the first axis,
wherein a metasurface is arranged between the bottom side of the top layer and the top side of the at least one intermediate layer and between the top side of the bottom layer and the bottom side of the at least one intermediate layer to surround the elongated waveguide channel,
wherein the elongated waveguide channel is provided with a central conductor suspended in the first and second portion, wherein a width of the first portion of the central conductor is tapered at the junction such that the width of the central conductor decreases from the first end towards the junction and from the second end towards the junction.

40. The multi-layer waveguide T-junction according to claim 39, wherein the first portion of the central conductor has a distal side and a proximal side, the proximal side being closer to the third end, and wherein the second portion of the central conductor is connected to the proximal side of the first portion of the central conductor,
wherein the distal side of the second portion of the central conductor tapers towards the proximal side at the junction, and/or
wherein the width of the second portion of the central conductor increases from a first width to a second width at the connection to the proximal side of the second portion of the central conductor.
